(19) United States
(12) Patent Application Publication
(10) Pub. No.: US 2026/0107394 A1
(43) Pub. Date: Apr. 16, 2026

(54) DISPLAY DEVICE

(71) Applicant: Sharp Display Technology Corporation, Kameyama City (JP)

(72) Inventors: Hisashi WATANABE, Kameyama City (JP); Hirotoshi YASUNAGA, Kameyama City (JP)

(21) Appl. No.: 19/353,941

(22) Filed: Oct. 9, 2025

(30) Foreign Application Priority Data
Oct. 10, 2024 (JP) 2024-178296

(51) Int. Cl. H05K 5/02

(52) U.S. Cl. CPC H05K 5/0217

(57) ABSTRACT

A display device includes a display panel, a housing that stores the display panel and includes a bezel placed around the display panel in a plan view, a front plate placed on a viewing side of the display panel and overlapping the display panel and at least part of the bezel in a plan view, and an adhesive member placed between the bezel and the front plate, and an absolute value of a difference between an SCI of a region overlapping the display panel in a plan view and an SCI of a region overlapping the bezel in a plan view is 3.0% or less, and an absolute value of a difference between an SCE of the region overlapping the display panel in a plan view and an SCE of the region overlapping the bezel in a plan view is 3.0% or less.

### CROSS-REFERENCE TO RELATED APPLICATIONS

This application claims the benefit of priority to Japanese Patent Application Number 2024-178296 filed on Oct. 10, 2024. The entire contents of the above-identified application are hereby incorporated by reference.

### BACKGROUND

### Technical Field

The disclosure relates to a display device.

In recent years, studies have been conducted on ways to improve design of display devices that display desired images when a display screen is on, by making a display panel inconspicuous by harmonizing with surrounding components, a housing, and the like when the display device is off.

For example, JP 5725581 B discloses a printed matter including a base film, a first color pattern layer provided on the base film and including multiple first color dots, a second color pattern layer provided on the first color pattern layer and including multiple second color dots, and a third color pattern layer provided on the second color pattern layer and including multiple third color dots, in which each of the first color dots includes a first color binder and multiple first color pigment chips dispersed inside the first color binder, each of the second color dots includes a second color binder and multiple second color pigment chips dispersed inside the second color binder, each of the third color dots includes a third color binder and multiple third color pigment chips dispersed inside the third color binder, each of the first color pigment chip, the second color pigment chip, and the third color pigment chip is any one of a red interference pigment, a green interference pigment, and a blue interference pigment that develop a color as interference light on a reflected light side, and the interference light is additively mixed, and discloses that the printed matter can be used in a display device.

### SUMMARY

The printed matter disclosed in JP 5725581 B is provided with a transmissive smoke printed layer, and when the printed matter is bonded to a display device, transmittance may be lowered. In addition, in the related art, when a front plate and a bezel of a housing are bonded together with an adhesive layer or the like, an appearance of a bonded portion where the adhesive layer or the like is placed is different from an appearance of a non-bonded portion where the adhesive layer or the like is not placed, and the bonded portion may be noticeable.

An object of the disclosure is to provide a display device in which a bonded portion where a bezel and a front plate are bonded together with an adhesive member is not noticeable.

(1) A display device according to an embodiment of the disclosure includes a display panel, a housing configured to store the display panel and including a bezel placed around the display panel in a plan view, a front plate placed on a viewing side of the display panel, and overlapping the display panel and at least part of the bezel in a plan view, and an adhesive member placed between the bezel and the front plate, in which an air layer is provided between the display panel and the front plate, and in a case in which α1 denotes a reflectance of a region overlapping the display panel in a plan view measured by an SCI method from a front plate side, 31 denotes a reflectance of a region overlapping the bezel in a plan view measured by the SCI method from the front plate side, α2 denotes a reflectance of the region overlapping the display panel in a plan view measured by an SCE method from the front plate side, and β2 denotes a reflectance of the region overlapping the bezel in a plan view measured by the SCE method from the front plate side, an absolute value of a difference between α1 and β1 is 3.0% or less, and an absolute value of a difference between α2 and β2 is 3.0% or less.

(2) In a display device according to an embodiment of the disclosure, in addition to the configuration in (1), the absolute value of the difference between α1 and β1 is 1.5% or less, and the absolute value of the difference between α2 and β2 is 1.5% or less.

(3) In a display device according to an embodiment of the disclosure, in addition to the configuration in (1) or (2), the adhesive member includes a light absorption layer and a reflective metal layer.

(4) In a display device according to an embodiment of the disclosure, in addition to the configuration in (3), the adhesive member includes, from the viewing side, the light absorption layer and the reflective metal layer in this order.

(5) In a display device according to an embodiment of the disclosure, in addition to any one of the configurations in (1) to (4), a surface of the adhesive member on the viewing side is formed of a first adhesive layer.

(6) In a display device according to an embodiment of the disclosure, in addition to any one of the configurations in (1) to (5), a surface of the adhesive member on a back side is formed of a second adhesive layer.

(7) In a display device according to an embodiment of the disclosure, in addition to any one of the configurations in (1) to (6), a reflectance of β2 relative to β1 is less than 5%.

(8) In a display device according to an embodiment of the disclosure, in addition to any one of the configurations in (1) to (7), the adhesive member overlaps part of the bezel in a plan view.

(9) In a display device according to an embodiment of the disclosure, in addition to any one of the configurations in (1) to (8), the adhesive member overlaps an entire surface of the bezel in a plan view.

(10) In a display device according to an embodiment of the disclosure, in addition to any one of the configurations in (1) to (9), part of the adhesive member overlaps part of the display panel in a plan view.

(11) In a display device according to an embodiment of the disclosure, in addition to any one of the configurations in (1) to (10), the adhesive member includes a light blocking layer.

(12) In a display device according to an embodiment of the disclosure, in addition to any one of the configurations in (1) to (11), the front plate includes a design layer.

(13) In a display device according to an embodiment of the disclosure, in addition to any one of the configurations in (1) to (12), the front plate has a total light transmittance of 5% or more.

(14) In a display device according to an embodiment of the disclosure, in addition to any one of the configurations in (1) to (13), local dimming is possible.

According to the disclosure, it is possible to provide a display device in which a bonded portion where a bezel and a front plate are bonded together with an adhesive member is not noticeable.

### BRIEF DESCRIPTION OF DRAWINGS

The disclosure will be described with reference to the accompanying drawings, wherein like numbers reference like elements.

FIG. 1 is a schematic plan view of a display device according to a first embodiment.

FIG. 2 is a schematic cross-sectional view taken along line X1-X2 in FIG. 1.

FIG. 3 is an enlarged schematic cross-sectional view of a bonded portion of a bezel and a front plate surrounded by a dotted line in FIG. 2.

FIG. 4 is a schematic cross-sectional view illustrating a first example 400A of an adhesive member that can be used in the first embodiment.

FIG. 5 is a schematic cross-sectional view illustrating a second example 400B of an adhesive member that can be used in the first embodiment.

FIG. 6 is a schematic cross-sectional view illustrating a third example 400C of an adhesive member that can be used in the first embodiment.

FIG. 7 is a schematic plan view illustrating an example of an arrangement of an adhesive member 400 in a display device according to the first embodiment.

FIG. 8 is a schematic plan view illustrating another example of an arrangement of the adhesive member 400 in the display device according to the first embodiment.

FIG. 9 is a schematic plan view illustrating a modified example of the first embodiment, describing a case in which an image is displayed on a display device capable of local dimming.

FIG. 10 is a schematic cross-sectional view illustrating a fourth example 400D of an adhesive member that can be used in a second embodiment.

FIG. 11 is a schematic cross-sectional view illustrating a fifth example 400E of an adhesive member that can be used in the second embodiment.

FIG. 12 is a schematic cross-sectional view illustrating a sixth example 400F of an adhesive member that can be used in the second embodiment.

FIG. 13 is a schematic plan view of a display device according to the second embodiment.

FIG. 14 is an enlarged schematic cross-sectional view of the display device according to the second embodiment, illustrating an adhesive portion of a bezel 310 and a front plate 110, and surroundings thereof.

FIG. 15 is a schematic cross-sectional view of a display device according to a third embodiment.

FIG. 16 is a schematic plan view of the display device according to the third embodiment.

FIG. 17 is a schematic plan view of a typical display device according to a first comparative embodiment.

FIG. 18 is a schematic cross-sectional view of the typical display device according to the first comparative embodiment.

FIG. 19 is an enlarged schematic cross-sectional view for describing reflection of external light in a region surrounded by a dotted line in FIG. 18.

FIG. 20 is a schematic plan view of a typical display device according to a second comparative embodiment.

FIG. 21 is a schematic cross-sectional view of the typical display device according to the second comparative embodiment.

FIG. 22 is an enlarged schematic cross-sectional view for describing reflection of external light in a region surrounded by a dotted line in FIG. 21.

FIG. 23 is a schematic plan view of a typical display device according to a third comparative embodiment.

FIG. 24 is a schematic cross-sectional view of the typical display device according to the third comparative embodiment.

FIG. 25 is an enlarged schematic cross-sectional view for describing reflection of external light in a region surrounded by a dotted line in FIG. 24.

FIG. 26 is a schematic plan view of a typical display device, describing an aspect in which a front plate includes a design layer.

FIG. 27 is a schematic cross-sectional view of an adhesive member prepared for a second experimental example.

FIG. 28 is a schematic cross-sectional view of a display device using an adhesive member for a first experimental example. The same applies to a display device using the adhesive member for the second experimental example.

### DESCRIPTION OF EMBODIMENTS

The disclosure will be described in detail below through the presentation of embodiments with reference to the drawings, however, the disclosure is not limited only to these embodiments. In the following description, the same reference numerals will be appropriately used in common among the different drawings for the same parts or parts having similar functions, and repeated description thereof will be omitted as appropriate. Each of the aspects of the disclosure may be combined as appropriate within a scope that does not depart from the gist of the disclosure.

In this specification, when two directions (planes) are orthogonal to each other, an angle between the two directions (planes) is preferably in a range of 90°±3°, more preferably in a range of 90°±1°, and even more preferably in a range of 90°±0.5°. When two directions (planes) are parallel, an angle between the two directions (planes) is preferably in a range of 0°±3°, more preferably in a range of 0°±1°, and even more preferably in a range of 0°±0.5°.

In this specification, when a target component is placed facing a viewer, a viewing side means a side closer to the viewer relative to the target component, and a back side means a side farther from the viewer relative to the target component. In this specification, plan view means a view from the viewing side.

In this specification, a display device being on refers to a state in which light is emitted from the viewing side of the display device. When a display panel is a liquid crystal panel, a display device being on refers to a state in which a backlight placed on a back side of the liquid crystal panel is on and the liquid crystal panel transmits light (white display state), and when the display panel is a self-luminous panel such as an OLED, a display device being on refers to a state in which the display panel is on. A display device being an off state refers to a state in which no light is emitted from the viewing side of the display device. When the display panel is a liquid crystal panel, the display device being off state refers to a state in which a backlight is off, and a state in which backlights corresponding to regions (black display regions) of the display panel where no image is being displayed are off in a display device equipped with backlights that can be locally dimmed. When the display panel is a self-luminous panel such as an OLED panel, the display device being off state refers to a state in which the display panel is an off state.

### First Embodiment

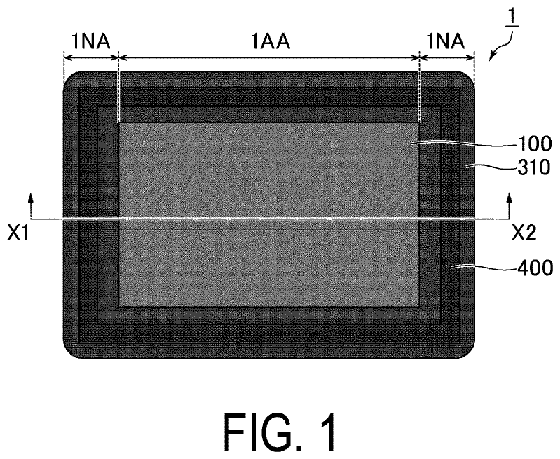

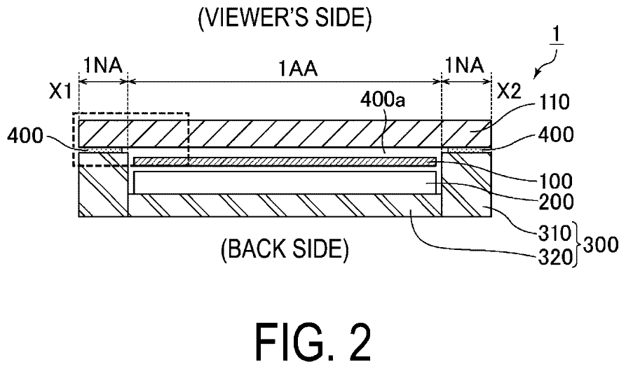

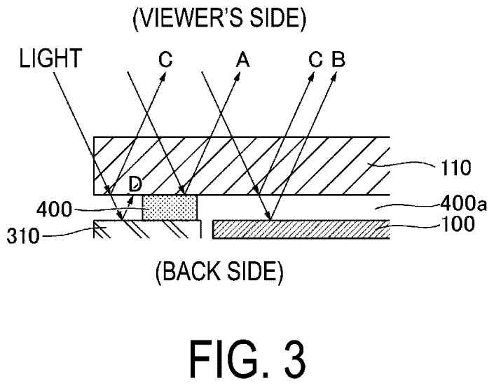

FIG. 1 is a schematic plan view of a display device according to a first embodiment. FIG. 2 is a schematic cross-sectional view taken along line X1-X2 in FIG. 1. FIG. 3 is an enlarged schematic cross-sectional view of a bonded portion of a bezel and a front plate surrounded by a dotted line in FIG. 2. A display device 1 according to the present embodiment includes a display panel 100, a housing 300 that stores the display panel 100 and includes a bezel 310 that is placed around the display panel 100 in a plan view, a front plate 110 that is placed on a viewing side of the display panel 100 and overlaps the display panel 100 and at least part of the bezel 310 in a plan view, and an adhesive member 400 that is placed between the bezel 310 and the front plate 110. An air layer 400a is provided between the display panel 100 and the front plate 110.

### Housing

As illustrated in FIG. 2, the display device 1 includes the housing 300 that stores the display panel 100. The housing 300 includes a bottom 320 and the bezel 310 that is provided around the bottom 320 and protrudes toward the viewing side. In a plan view, the bottom 320 overlaps the display panel 100, and the bezel 310 is placed around the display panel 100. For example, by placing the adhesive member 400 on the back side of the front plate 110 overlapping a frame region 1NA and bonding the adhesive member 400 to the bezel 310, the front plate 110 can be fixed to the housing 300. A face of the bezel 310 is preferably horizontal on the viewing side, and the bezel 310 is bonded to the front plate 110 with the adhesive member 400 on the horizontal face.

The housing 300 may store, for example, a circuit substrate (not illustrated) on which a drive circuit for driving the display panel 100 and a backlight 200 is formed. The housing 300 is not particularly limited as long as the display panel 100 and the front plate 110 can be stored therein, and may be made of metal or resin. A shape of the housing 300 is not limited to a box shape with an open top as illustrated in FIG. 2. The bottom 320 and the bezel 310 may be integrally formed.

### Display Panel

As illustrated in FIG. 1, the display panel 100 has, in a plan view, a display region 1AA and the frame region 1NA placed around the display region 1AA. The frame region 1NA is a region that overlaps the bezel 310 in a plan view and is a region that is not involved in displaying images and the like on the display device. The display region 1AA is a region that overlaps the display panel 100 in a plan view. The display region 1AA is specifically a region including multiple pixels, and is a region where desired images and the like are displayed during transmissive display.

Examples of the display panel 100 include a liquid crystal panel and a self-luminous panel such as an OLED panel. The liquid crystal panel is composed of, for example, a pair of substrates and a liquid crystal layer that is sandwiched between the pair of substrates and contains liquid crystal molecules. The pair of substrates may be a TFT substrate including multiple switching elements such as thin film transistors (TFTs) and a counter substrate. The TFT substrate or the counter substrate may include color filters of red, green, blue, or the like that overlap pixels described below.

The TFT substrate may be composed of a support substrate, gate wiring lines and source wiring lines intersecting the gate wiring lines placed on the support substrate, TFTs placed near intersections of the gate wiring lines and the source wiring lines, and pixel electrodes electrically connected to the TFTs. A region surrounded by the gate wiring lines and the source wiring lines is the pixel, and the color filters are arranged so as to overlap the corresponding pixels.

A common electrode is placed on the TFT substrate or the counter substrate. By applying a predetermined voltage between the pixel electrode and the counter electrode, an electrical field is generated in the liquid crystal layer, and an orientation direction of the liquid crystal molecules is controlled to adjust an amount of transmission of light emitted from the backlight 200 to the liquid crystal panel, thereby providing transmissive display.

The liquid crystal panel includes a pair of polarizers on the viewing side and the back side. The pair of polarizers may be absorptive linear polarizers each having a transmission axis that transmits only light in a specific polarization direction and an absorption axis orthogonal to the transmission axis. The pair of polarizers are arranged, for example, in crossed Nicols such that the transmission axes thereof are orthogonal to each other. In addition, between the TFT substrate and the liquid crystal layer, and between the counter substrate and the liquid crystal layer, an alignment film that controls the orientation direction of the liquid crystal molecules when no voltage is applied may be placed.

An example of the self-luminous panel is an organic light emitting diode (OLED) panel including multiple OLEDs. The self-luminous panel is a panel that can emit light by itself with light-emitting elements such as OLEDs inside the panel, and can emit light to the viewing side without requiring an external light source such as a backlight.

A configuration of the organic light emitting diode is not particularly limited, and may be a configuration in which a cathode electrode, a light-emitting layer, and an anode electrode are layered in this order. The light-emitting layer may contain a fluorescent material, a phosphorescent material, or the like as a luminescent material. An electron transport layer may be placed between the cathode electrode and the light-emitting layer, and a hole transport layer may be placed between the light-emitting layer and the anode electrode.

The light-emitting elements such as OLEDs may be arranged in a matrix on a substrate on which, for example, gate wiring lines, source wiring lines, TFTs, and the like are formed, so that each TFT (each pixel) includes one light-emitting element. In the OLED panel, a region where multiple light-emitting elements are arranged is the display region. The multiple light-emitting elements may include red light-emitting elements, green light-emitting elements, and blue light-emitting elements. The self-luminous panel may include a circular polarizer on a front plate side (front side) from the viewpoint of reducing internal reflectance.

On the front side of the display panel 100, an anti-reflection film may be further placed on the front side of the polarizer such as the linear polarizer or the circular polarizer described above. Examples of the anti-reflection film include known films such as an anti-reflection film (AR film) and an anti-glare film (AG film). As the AR film, for example, an AR film manufactured by Dai Nippon Printing Co., Ltd. can be used. As the AG film, for example, an AG film manufactured by Dai Nippon Printing Co., Ltd. can be used.

### Front Plate

The front plate 110 is a component placed on the front side (viewing side) of the display panel 100, and transmits at least part of light incident from the display panel 100. The front plate 110 preferably includes a transparent base material (transparent base material 111 described below).

The transparent base material may be, for example, a plate made of resin such as acrylic or polycarbonate, or a glass plate. The transparent base material may have a flat surface or a curved surface.

From the viewpoint of maintaining high luminance of the display device, the transparent base material preferably has a high transmittance, for example, a transmittance of 90% or more. From the viewpoint of suppressing blurring of display images, the transparent base material preferably has a haze of 10% or less. In this specification, the transmittance refers to a total light transmittance, and is measured by a method in accordance with JIS K 7361-1:1997. The total light transmittance is a total light transmittance in a visible light region (e.g., wavelengths from 380 nm to 780 nm). The haze is measured by a method in accordance with JIS K 7136:2000. The total light transmittance can be measured, for example, using a turbidity meter such as “Haze Meter NDH 2000” manufactured by Nippon Denshoku Industries Co., Ltd. The haze can be measured, for example, using a turbidity meter such as “Haze Meter NDH 2000” manufactured by Nippon Denshoku Industries Co., Ltd.

A transmittance of a region of the front plate 110 that overlaps the display region 1AA is preferably 50% or more. With this aspect, the display device 1 can perform transmissive display while maintaining high luminance. When the transmittance of the region of the front plate 110 that overlaps the display region 1AA is less than 50%, the luminance of the display device 1 may decrease, and display images may be difficult to see in a bright environment. The transmittance of the region of the front plate 110 that overlaps the display region 1AA is more preferably 70% or more. An upper limit of the transmittance of the front plate 110 is, for example, 90%.

The front plate 110 preferably has a total light transmittance of 5% or more. As described below, the front plate 110 may include regions having different transmittances in an in-plane direction, but a total light transmittance of a region of the front plate 110 having the lowest transmittance, including a region overlapping the frame region 1NA and a region overlapping the display region 1AA of the front plate 110, is preferably 5% or more. In other words, it is preferable that the front plate 110 do not include a frame print portion or a structure that completely blocks light even in the frame region 1NA of the display panel in a plan view. The frame print portion may be a light blocking layer formed of, for example, black ink. As described below, a transmissive design layer may be provided, but even when the design layer is provided, it is preferable that the total light transmittance of the region of the front plate 110 having the lowest transmittance be 5% or more.

As illustrated in FIG. 3, the adhesive member 400 is placed between the bezel 310 and the front plate 110. The bezel 310 and the front plate 110 may be directly bonded together with the adhesive member 400, or may be bonded together with the adhesive member 400 and another adhesive layer, a double-sided tape, or the like. When the adhesive member 400 is used for direct bonding, it is preferable that the adhesive member 400 further include adhesive layers on the front side and the back side thereof, as will be described below. In this case, the front side of the adhesive member 400 is preferably in contact with the front plate 110 and the back side of the adhesive member 400 is preferably in contact with the bezel 310. The bezel 310 and the front plate 110 may be bonded with the adhesive member 400 and other adhesive layers, double-sided tapes, or the like, but it is preferable that at least the front side of the adhesive member 400 be in contact with the front plate 110. The front plate 110 has a larger area than the display panel 100 in a plan view, and is bonded to the bezel 310 at a portion outside the display panel in a plan view.

In FIG. 3, A denotes a surface reflectance of the adhesive member 400, B denotes a surface reflectance of the display panel 100, C denotes an interface reflectance between the front plate 110 and the air layer 400a, and D denotes a surface reflectance of the bezel 310 at a non-bonded portion. In the frame region 1NA, at the bonded portion where the adhesive member 400 is placed on the bezel 310, by adjusting the surface reflectance of the adhesive member 400 so that A=B+C, a boundary between the bonded portion and the non-bonded portion can be made less visible. When B and C are specular reflections, by making A closer to a specular reflection, reflection characteristics, including angular characteristics, can be made equivalent, and the bonded portion can be made less noticeable. At the non-bonded portion where the adhesive member 400 is not placed on the bezel 310, by adjusting a tone and the reflectance of the bezel 310 so that C+B=C+D, that is, B=D, a boundary between the bonded portion where the bezel 310 and the front plate 110 are bonded together with the adhesive member 400 and the display region 1AA can be made less visible.

When α1 denotes a reflectance of a region overlapping the display panel 100 in a plan view measured by an SCI method from the front plate 110 side, β1 denotes a reflectance of a region overlapping the bezel 310 in a plan view measured by the SCI method from the front plate 110 side, α2 denotes a reflectance of the region overlapping the display panel 100 in a plan view measured by an SCE method from the front plate 110 side, and β2 denotes a reflectance of the region overlapping the bezel 310 in a plan view measured by the SCE method from the front plate 110 side, an absolute value of a difference between α1 and β1 (|α1−β1|) is 3.0% or less, and an absolute value of a difference between α2 and β2 (|α2−β21) is 3.0% or less. Note that the region overlapping the bezel 310 in a plan view refers to the bonded portion where the adhesive member 400 is placed on the bezel 310 in a plan view. By making the absolute value of the difference between the reflectance of the display region and the reflectance of the bonded portion in the frame region measured by the SCI method, and the absolute value of the difference between the reflectance of the display region and the reflectance of the bonded portion in the frame region measured by the SCE method both 3.0% or less, the boundary between the display region and the bonded portion can be made less noticeable.

The reflectance measured by the SCE method (hereinafter, also referred to as SCE) is a reflectance with specularly reflected light removed, and is also referred to as a diffuse reflectance. The reflectance measured by the SCI method (hereinafter, also referred to as SCI) is a reflectance that includes specularly reflected light. The SCE and the SCI can be measured using, for example, a CM-700d spectrophotometer manufactured by KONICA MINOLTA INC., in accordance with JIS Z 8722:2009. In this specification, the reflectance and the transmittance refer to a reflectance and a transmittance in a visible light region (wavelengths 380 nm to 780 nm).

The SCE of the display region can be adjusted by, for example, surface roughness, a haze, or the like of a layer, a component, or the like placed on the front side of the display panel 100, and the larger the surface roughness, haze, or the like, the higher the SCE of the display region tends to be. For example, when an AG film or the like is placed on the display panel 100 to perform an anti-glare treatment, the SCE of the display region tends to be larger than that when the anti-glare treatment is not performed. However, regardless of whether a surface treatment of the display panel is performed or not, |α1−β1| and |α2-β21 are preferably 3.0% or less. The SCI of the display region can be reduced by, for example, placing an AR film or the like on the display panel 100.

The SCE of the frame region and the SCI of the frame region can be adjusted by adjusting the SCE and the SCI of the adhesive member 400. For example, when the adhesive member 400 includes a reflective metal layer 403 described below, the SCE and the SCI of the frame region can be increased by increasing a reflectance of the reflective metal layer 403. When surface roughness of the reflective metal layer 403 is large, in a case in which the adhesive member 400, which tends to have a high SCE of the frame region, includes a light absorption layer 402 described below, the SCE and the SCI of the frame region can be increased by increasing a total light transmittance of the light absorption layer 402. When the adhesive member 400 includes the light absorption layer 402 described below, the SCE and the SCI of the frame region can be increased by increasing a total light transmittance of the light absorption layer 402. When a haze of the light absorption layer 402 is high, the SCE of the frame region tends to be high. The SCE of the frame region and the SCI of the frame region can also be adjusted by making the reflection of the bezel 310 closer to a specular reflection at the non-bonded portion where the adhesive member 400 is not placed.

Preferably, |α1-β1| is 1.5% or less and |α2-β2| is 1.5% or less. With this aspect, the boundary between the display region and the bonded portion can be made less noticeable.

A reflectance of β2 relative to β1, (β2/β1)× 100 [%], is preferably less than 5.0%. When the reflectance of β2 relative to β1 is less than 5%, the reflection (reflectance A described in FIG. 3) of the bonded portion where the adhesive member 400 is placed on the bezel 310 is closer to a specular reflection. For example, when the front plate 110 and a component on the viewing side of the display panel 100 are glass or the like, the reflectances B and C described with reference to FIG. 3 are substantially specular reflections. Therefore, by making the reflection of the bonded portion closer to a specular reflection, the reflection characteristics of the display region and the bonded portion, including the angular characteristics, can be made equivalent, thereby making the bonded portion less noticeable. The reflectance of β2 relative to β1 is more preferably 3.0% or less.

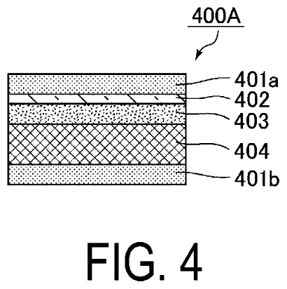

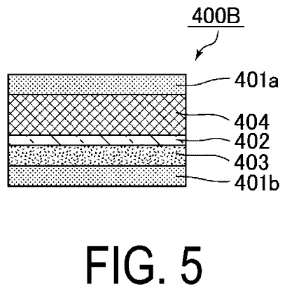

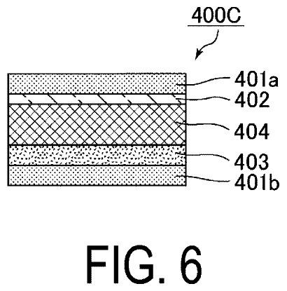

Adhesive members that can be used in the first embodiment will be described below. Note that adhesive members 400A to 400C will be described below as specific examples, but unless there is any need to distinguish between the specific examples, the adhesive members will be described as the adhesive member 400. FIG. 4 is a schematic cross-sectional view illustrating a first example 400A of an adhesive member that can be used in the first embodiment. FIG. 5 is a schematic cross-sectional view illustrating a second example 400B of an adhesive member that can be used in the first embodiment. FIG. 6 is a schematic cross-sectional view illustrating a third example 400C of an adhesive member that can be used in the first embodiment.

The adhesive member 400 of the first embodiment includes the light absorption layer 402 and the reflective metal layer 403. The light absorption layer 402 is semi-transparent and transmits some light incident from the viewing side and the back side, and absorbs the remaining light. The reflective metal layer 403 is a layer that reflects at least some light incident from the viewing side. Since the adhesive member 400 includes the reflective metal layer 403, the SCE and the SCI of the bonded portion can be increased. Since the adhesive member 400 includes the light absorption layer 402, the SCE and the SCI of the adhesive member 400 can be reduced compared with when only the reflective metal layer 403 is present, and the SCE and the SCI can be adjusted to desired ranges.

The adhesive member 400 preferably includes the light absorption layer 402 and the reflective metal layer 403 in this order from the viewing side. By placing the light absorption layer 402 on the front side relative to the reflective metal layer 403, an amount of light incident on the reflective metal layer 403, and an amount of light reflected by the reflective metal layer 403 and passing through the light absorption layer 402 can be reduced, thereby adjusting the SCE and the SCI of the adhesive member 400.

The reflective metal layer 403 is formed of a reflective metal. A material of the reflective metal layer 403 is preferably one that can be formed into a thin film, such as aluminum, silver, chromium, nickel, tantalum, tungsten, or an alloy thereof.

The reflective metal layer 403 can be formed by, for example, sputtering, vapor deposition, chemical vapor deposition (CVD), or the like. In particular, it is preferable to form the reflective metal layer 403 by sputtering. As described below, the adhesive member 400 may include a base material 404, and when the adhesive member 400 includes the base material 404, the reflective metal layer 403 may be formed on the base material 404.

The reflectance (specular reflectance) of the reflective metal layer 403 is preferably 40% or more, more preferably 60% or more, and still more preferably 80% or more. The reflectance of the reflective metal layer 403 can be measured using, for example, a CM-700d spectrophotometer manufactured by KONICA MINOLTA INC., in accordance with JIS Z 8722. The reflectance of the reflective metal layer 403 can be adjusted by a type, a thickness, surface roughness, or the like of the metal used.

A thickness of the reflective metal layer 403 is, for example, preferably from 30 nm to 300 nm, and more preferably from 70 nm to 150 nm. Although not illustrated, the reflective metal layer 403 may also serve as the base material 404. For example, when the reflective metal layer 403 is aluminum foil or the like, the reflective metal layer 403 can also serve as the base material 404. When the reflective metal layer 403 serves as the base material 404, a thickness of the reflective metal layer 403 is preferably from 6 μm to 200 μm, and more preferably from 10 μm to 100 μm.

The light absorption layer 402 may be a printed layer, a colored resin sheet containing a colorant, or the like. The printed layer may be, for example, a layer printed with ink containing a colorant and a binder resin. A printing method is not limited, and known printing methods such as screen printing and gravure printing can be used. The colored resin sheet may be, for example, a resin composition containing a colorant formed into a sheet. The resin composition is not limited. The colorant is preferably a black colorant, and examples thereof include black pigments such as carbon black. The transmittance of the light absorption layer 402 can be adjusted by changing an amount of the colorant added or the thickness of the printed layer or the colored resin sheet.

When the light absorption layer 402 is a printed layer, a thickness of the printed layer is preferably from 3 μm to 100 μm, and more preferably from 5 μm to 30 μm. Although not illustrated, when the light absorption layer 402 is a colored resin sheet containing a colorant, the light absorption layer 402 may also serve as the base material 404. When the light absorption layer 402 serves as the base material 404, a thickness of the light absorption layer 402 is preferably from 6 μm to 200 μm, and more preferably from 10 μm to 100 μm.

The total light transmittance of the light absorption layer 402 is preferably from 18% to 30%, and more preferably from 20% to 30%.

The adhesive member 400 may further include the base material 404, and as in the first example 400A of the adhesive member illustrated in FIG. 4, a light absorption layer 402 and a reflective metal layer 403 may be placed on a front side relative to a base material 404. In the first example 400A, the light absorption layer 402, the reflective metal layer 403, and the base material 404 may be placed in this order from the viewing side, and the light absorption layer 402 and the reflective metal layer 403, and the reflective metal layer 403 and the base material 404 may be in contact with each other.

The base material 404 is a sheet made of resin, and the resin base material may be polyethylene terephthalate (PET), acrylic, polycarbonate, polypropylene, or polystyrene.

A thickness of the base material 404 is preferably from 25 μm to 300 μm, and more preferably from 50 μm to 200 μm.

As in the second example 400B of the adhesive member illustrated in FIG. 5, a light absorption layer 402 and a reflective metal layer 403 may be placed on a back side relative to a base material 404. In the second example 400B, the base material 404, the light absorption layer 402, and the reflective metal layer 403 may be placed in this order from the viewing side, and the base material 404 and the light absorption layer 402, and the light absorption layer 402 and the reflective metal layer 403 may be in contact with each other. The adhesive member of the second example 400B is obtained, for example, by forming the light absorption layer 402 on the base material 404 and then forming the reflective metal layer 403 on the light absorption layer 402.

In the first example 400A, a color and a transmittance of the base material 404 are not limited, but in the second example 400B, the base material 404 is preferably a transparent resin base material, and for example, a total light transmittance thereof is preferably 80% or more, and more preferably 90% or more. The base material 404 preferably has a haze of 10% or less.

As in the third example 400C of the adhesive member illustrated in FIG. 6, a light absorption layer 402 may be placed on a front side relative to a base material 404, and a reflective metal layer 403 may be placed on a back side relative to the base material 404. In the third example 400C, the light absorption layer 402, the base material 404, and the reflective metal layer 403 may be placed in this order from the viewing side, and the base material 404 and the light absorption layer 402, and the base material 404 and the reflective metal layer 403 may be in contact with each other. The adhesive member of the third example 400C is obtained, for example, by forming one of the light absorption layer 402 and the reflective metal layer 403 on one surface of the base material 404 on the viewing side or the back side, and forming the other of the light absorption layer 402 and the reflective metal layer 403 on the other surface of the base material 404. Either the light absorption layer 402 or the reflective metal layer 403 may be formed first.

From the viewpoint of making reflection of the base material 404 on a front plate 110 side closer to a specular reflection, it is preferable that a surface on a side on which the reflective metal layer 403 is placed be flat, for example, with an arithmetic mean roughness Ra of 1 μm or less. The arithmetic mean roughness Ra can be measured using, for example, a laser microscope VK-X3000 manufactured by KEYENCE CORPORATION, in accordance with JIS B 0601:2001.

The adhesive member 400 preferably includes adhesive layers. In the first embodiment, the adhesive member 400 is a double-sided tape in which a surface on the viewing side is formed of a first adhesive layer 401a and a surface on the back side is formed of a second adhesive layer 401b. When the front plate 110 and the bezel 310 are bonded together using only the adhesive member 400, the first adhesive layer 401a is in contact with the front plate 110, and the second adhesive layer 401b is in contact with the bezel 310.

An acrylic adhesive, a silicon adhesive, or the like can be used for the first adhesive layer 401a. As the first adhesive layer 401a, LUCIACS CS986 manufactured by Nitto Denko Corporation, or the like can be used. The first adhesive layer 401a is preferably transparent, and a total light transmittance thereof is preferably 80% or more. The second adhesive layer 401b may be similar to the first adhesive layer 401a, but the second adhesive layer 401b does not have to be transparent, and a color and a transmittance thereof are not limited.

Thicknesses of the first adhesive layer 401a and the second adhesive layer 401b are preferably from 10 μm to 100 μm, and more preferably from 20 μm to 50 μm. The thickness of the first adhesive layer 401a and the thickness of the second adhesive layer 401b may be the same or different.

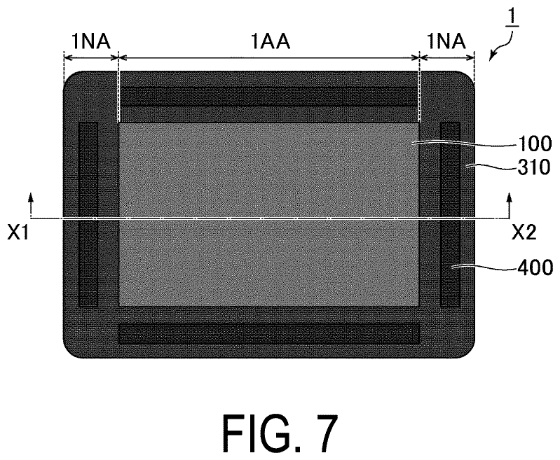

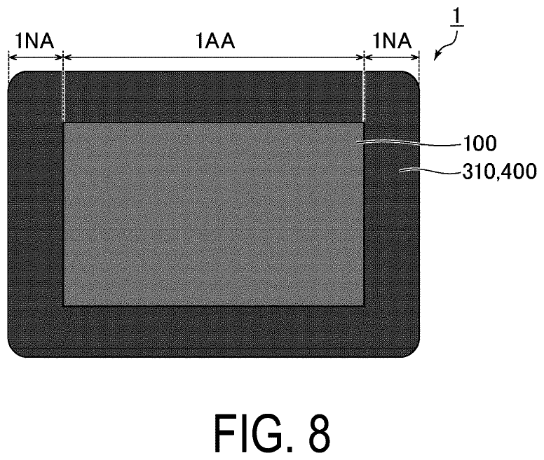

FIG. 7 is a schematic plan view illustrating an example of an arrangement of an adhesive member 400 in a display device according to the first embodiment. FIG. 8 is a schematic plan view illustrating another example of an arrangement of an adhesive member 400 in a display device according to the first embodiment. In the first embodiment, the adhesive member 400 is preferably placed so as not to extend outside the bezel 310 in a plan view. For example, the adhesive member 400 may be placed so as to surround the display panel 100 as illustrated in FIG. 1, or may be divided into multiple pieces and placed on the bezel 310 as illustrated in FIG. 7. As illustrated in FIGS. 1 and 7, the adhesive member 400 may be placed so as to overlap part of the bezel 310 in a plan view.

As illustrated in FIGS. 1 and 7, when there is a portion of the bezel 310 where the adhesive member 400 is not placed, it is preferable to make reflection of a surface of the bezel 310 on the viewing side at the non-bonded portion where the adhesive member 400 is not placed closer to a specular reflection. By making the reflection of the bezel 310 closer to a specular reflection, the SCI and the SCE of the non-bonded portion where the adhesive member 400 is not placed can be made closer to the SCI and the SCE of the display region, thereby making the boundary between the non-bonded portion and the display region less noticeable.

A method of making the reflection of the surface of the bezel 310 on the viewing side closer to a specular reflection is, for example, to make an arithmetic mean roughness Ra of the surface of the bezel 310 on the viewing side 1 μm or less.

In FIGS. 1 and 7, a width of the adhesive member 400 may be narrower than a width of the bezel 310. In a plan view, the width of the adhesive member 400 is, for example, preferably from 300 μm to 2.0 cm, and more preferably from 500 μm to 1.0 cm. Note that the first adhesive layer 401a, the light absorption layer 402, the reflective metal layer 403, the base material 404, and the second adhesive layer 401b included in the adhesive member 400 all have the same width.

As illustrated in FIG. 8, an adhesive member 400 may be placed so as to overlap an entire surface of a bezel 310 in a plan view. In FIG. 8, a width of the adhesive member 400 is the same as a width of the bezel 310. By placing the adhesive member 400 so as to overlap the entire surface of the bezel 310 in a plan view, the boundary between the display region and the frame region can be made less noticeable.

A thickness of the adhesive member 400 is preferably from 50 μm to 1 mm, more preferably from 50 μm to 500 μm, and still more preferably from 75 μm to 300 μm.

### Backlight

As illustrated in FIG. 2, the backlight 200 may be placed on the back side of the display panel 100. In particular, when the display panel 100 is a liquid crystal panel, the display device 1 preferably includes the backlight 200.

The backlight 200 may be any known type such as an edge-lit backlight in which light-emitting elements are arranged on an end face of a light guide plate, or a direct backlight in which a large number of light-emitting elements are arranged in a plane and uniformity is improved using a diffuser plate or the like. The light-emitting element may be any known type in the field of backlight such as a light emitting diode (LED), a fluorescent lamp, or a cold cathode tube.

### Display Method

When the display device 1 is on, light (display light) emitted from the display panel side passes through the front plate, is emitted to the viewing side, and provides transmissive display that allows the viewer to view any image and the like displayed on the display panel. When the display panel is a liquid crystal panel, the transmissive display can be performed by turning on the backlight while the liquid crystal panel is in a white display state. By aligning the liquid crystal molecules so as to form an angle with the transmission axis of the polarizer, a white display state is obtained in which light emitted from the backlight is transmitted to the viewing side, and when the orientation direction of the liquid crystal molecules forms an angle of 45° with the transmission axis of the polarizer, the transmittance is maximized. By aligning the liquid crystal molecules so as to be substantially parallel to the transmission axis of the polarizer, light transmitted to the viewing side is blocked by the liquid crystal layer even when the backlight is on, resulting in a black display state.

The bezel 310 preferably has a similar appearance to the display panel 100 when the display device 1 is off. To be specific, in a plan view, a region overlapping the display panel 100 is defined as the display region 1AA, and a region overlapping the bezel 310 is defined as the frame region 1NA, and when the display device 1 is off, an x value and a y value in an xy chromaticity diagram of the display region 1AA measured from the viewing side are defined as x_{α-1} and y_{α-1}, respectively, and an x value and a y value in an xy chromaticity diagram of the frame region 1NA measured from the viewing side are defined as x_{β-1} and y_{β-1}, respectively. Absolute values of a difference between x_{α-1} and X3-1 and a difference between y_{α-1} and y_{β-1} are both preferably 0.02 or less. The display device 1 having such an aspect can make a boundary between the bezel 310 and the display panel 100 even less visible, thereby achieving a better appearance.

x_{α-1} is preferably from 0.293 to 0.333 and y_{α-1} is preferably from 0.309 to 0.349, and X3-1 is preferably from 0.293 to 0.333 and y_{β-1} is preferably from 0.309 to 0.349. The display device 1 having such an aspect can achieve a sober appearance without being too flashy.

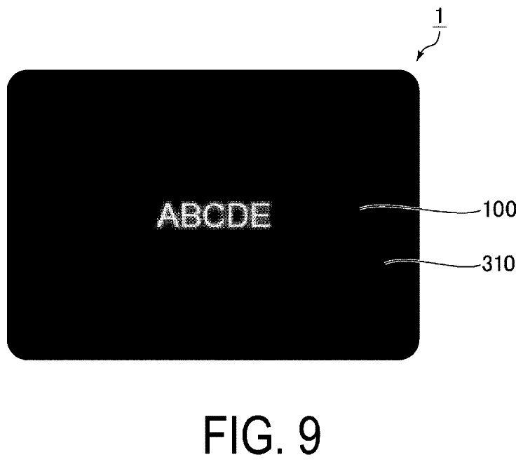

FIG. 9 is a schematic plan view illustrating a modified example of the first embodiment, describing a case in which an image is displayed on a display device capable of local dimming. Note that in FIG. 9, difference in appearance between a display panel 100 and a bezel 310 is omitted.

The local dimming, also referred to as partial drive, is a display method in which the display region 1AA is divided into multiple regions (dimming areas) and luminance (light emission intensity) is adjusted for each region. An example of the display device 1 capable of local dimming is a display device further including a backlight 200 that is placed on a back side of the display panel 100 and is capable of local dimming.

The backlight 200 is preferably a direct backlight. As the backlight 200, an OLED panel including OLEDs as light-emitting elements may be used. The display device 1 further includes a luminance adjustment mechanism that adjusts luminance of the backlight 200. The luminance adjustment mechanism preferably adjusts light emission intensity of each of the multiple light-emitting elements for divided regions in accordance with a display image of the liquid crystal panel. Note that when an organic EL display is used as the display panel, pixels in an off state are displayed in black, resulting in an appearance similar to that of the backlight placed on the back side of the liquid crystal display being locally dimmed. The appearance is similar to when the backlight is used.

The local dimming can be used for achieving a sophisticated design of the display device 1 in which a picture (a string of letters ABCDE in FIG. 9) appears on a black background, as illustrated in FIG. 9. The local dimming changes brightness (luminance) of the backlight according to brightness of each dimming area of the display panel. In the dimming area where bright images and the like are displayed, the luminance of the backlight is increased, and in the dimming area where dark images and the like are displayed, the luminance of the backlight is decreased. In the dimming area where only black is displayed, the luminance of the backlight is further reduced or the backlight is turned off. In portions of the display region 1AA that are in a black display state, the same black color as when the backlight 200 is off can be achieved, thereby providing a good appearance.

### Second Embodiment

In a second embodiment, an adhesive member 400 includes a light blocking layer 405. The light blocking layer 405 may be any layer that has light blocking properties, and a specific example of the light blocking layer 405 is a layer printed with black ink. A printing method is not limited, and known printing methods such as screen printing and gravure printing can be used. A total light transmittance of the light blocking layer 405 is, for example, 2% or less.

The light blocking layer 405 is preferably placed on a back side relative to a reflective metal layer 403. Pinholes may be formed in the reflective metal layer 403 due to moisture or the like during thin film formation, and a bezel 310 may be visible through the pinholes. By placing the light blocking layer 405 on the back side relative to the reflective metal layer 403, even when pinholes are formed in the reflective metal layer 403, it is possible to prevent the bezel 310 from being seen through the pinholes. The light blocking layer 405 and the reflective metal layer 403 are preferably in contact with each other. Considering that the light absorption layer 402 is semi-transparent, the light blocking layer 405 is more preferably placed on the back side relative to the light absorption layer 402.

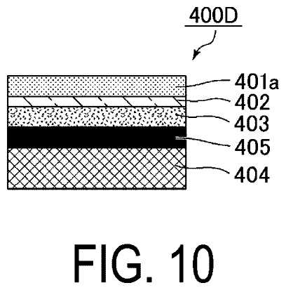

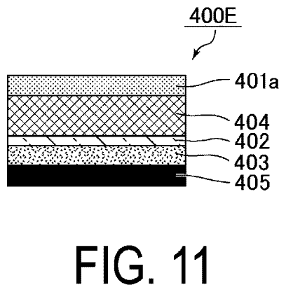

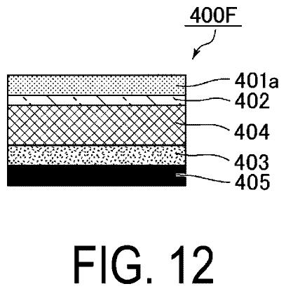

Adhesive members that can be used in the second embodiment will be described below. Note that adhesive members 400D to 400F will be described below as specific examples, but unless there is any need to distinguish between the specific examples, the adhesive members will be described as the adhesive member 400. FIG. 10 is a schematic cross-sectional view illustrating a fourth example 400D of an adhesive member that can be used in the second embodiment. FIG. 11 is a schematic cross-sectional view illustrating a fifth example 400E of an adhesive member that can be used in the second embodiment. FIG. 12 is a schematic cross-sectional view illustrating a sixth example 400F of an adhesive member that can be used in the second embodiment.

In the second embodiment, the adhesive member 400 may also include a base material 404, and as in the fourth example 400D of the adhesive member illustrated in FIG. 10, a light absorption layer 402, a reflective metal layer 403, and a light blocking layer 405 may be placed on a front side relative to a base material 404. In the fourth example 400D, the light absorption layer 402, the reflective metal layer 403, the light blocking layer 405, and the base material 404 may be placed in this order from the viewing side, and the light absorption layer 402 and the reflective metal layer 403, the reflective metal layer 403 and the light blocking layer 405, and the light blocking layer 405 and the base material 404 may be in contact with each other.

As in the fifth example 400E of the adhesive member illustrated in FIG. 11, a light absorption layer 402 and a reflective metal layer 403 may be placed on a back side relative to a base material 404. In the fifth example 400E, the base material 404, the light absorption layer 402, the reflective metal layer 403, and a light blocking layer 405 may be placed in this order from the viewing side, and the base material 404 and the light absorption layer 402, the light absorption layer 402 and the reflective metal layer 403, and the reflective metal layer 403 and the light blocking layer 405 may be in contact with each other.

As in the sixth example 400F of the adhesive member illustrated in FIG. 12, a light absorption layer 402 may be placed on a front side relative to a base material 404, and a reflective metal layer 403 and a light blocking layer 405 may be placed on a back side relative to the base material 404. In the sixth example 400F, the light absorption layer 402, the base material 404, the reflective metal layer 403, and the light blocking layer 405 may be placed in this order from the viewing side, and the light absorption layer 402 and the base material 404, the base material 404 and the reflective metal layer 403, and the reflective metal layer 403 and the light blocking layer 405 may be in contact with each other.

In the second embodiment, the adhesive member 400 is preferably configured such that a surface on the viewing side is formed of the first adhesive layer 401a described above.

When a width of the adhesive member 400 is narrower than a width of a bezel, the adhesive member 400 may be placed so as to overlap part of the bezel 310 in a plan view as illustrated in FIGS. 1 and 7 described in the first embodiment. In addition, when the width of the adhesive member 400 is the same as the width of the bezel, the adhesive member 400 may be placed so as to overlap an entire surface of the bezel 310 in a plan view as illustrated in FIG. 8 described in the first embodiment. When the width of the adhesive member 400 is narrower than or equal to the width of the bezel, the adhesive member 400 may have the second adhesive layer 401b on the back side as in the first embodiment, although not illustrated. The first adhesive layer 401a and the second adhesive layer 401b may be similar to those described in the first embodiment.

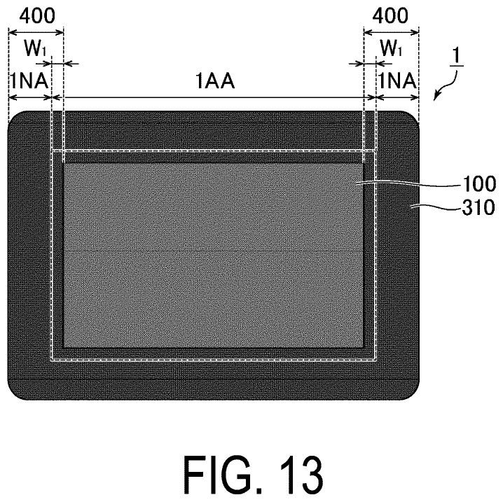

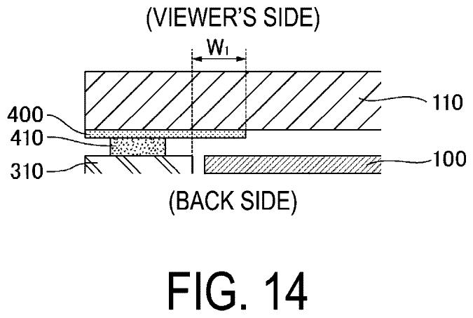

FIG. 13 is a schematic plan view of a display device according to the second embodiment. FIG. 14 is an enlarged schematic cross-sectional view of the display device according to the second embodiment, illustrating an adhesive portion of the bezel 310 and a front plate 110, and surroundings thereof. Part of the adhesive member 400 may overlap part of a display panel 100 in a plan view. By placing the adhesive member 400 so as to overlap part of the display panel, in other words, by placing the adhesive member 400 so that part of the adhesive member 400 extends outside the bezel 310 toward a display panel 100 side, the adhesive member 400 can also be placed over a gap between the bezel 310 and the display panel 100. With this aspect, light from a backlight or the like leaking through the gap can be blocked, thereby improving an appearance of the display device.

In FIGS. 13 and 14, a width of the adhesive member 400 is preferably wider than a width of the bezel 310, and is, for example, from 0.3 cm to 1 cm in a plan view. In a plan view, a distance W1 from an end portion of the bezel 310 on a display panel 100 side to an end portion of the adhesive member 400 on the display panel 100 side (a width of the adhesive member 400 extending outside toward the display panel 100 side) is preferably from 2 mm to 5 mm.

In FIGS. 13 and 14, the adhesive member 400 is preferably a single-sided tape that does not have the second adhesive layer 401b described above on the back side, and the adhesive member 400 and the bezel 310 may be bonded together using a separate fixing tape 410. The fixing tape 410 is not limited, and examples thereof include a known adhesive layers and a double-sided tape. For example, a double-sided tape similar to a double-sided tape 301TR illustrated in a second comparative embodiment described below can be used.

### Third Embodiment

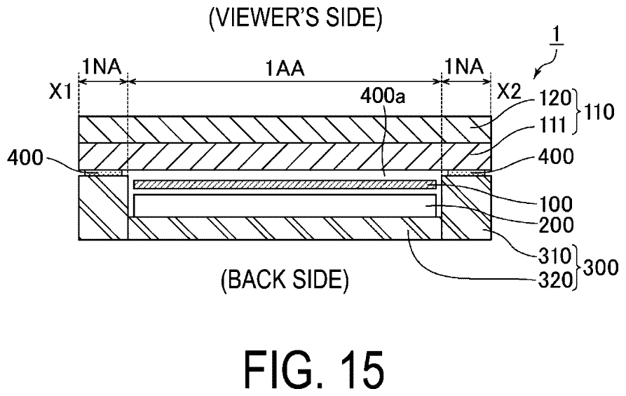

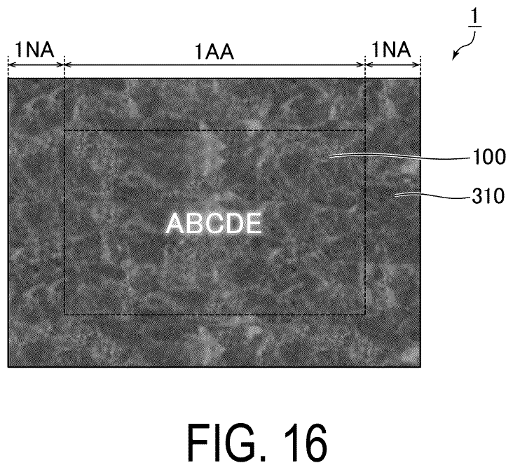

In a display device according to a third embodiment, a front plate 110 includes a design layer 120. FIG. 15 is a schematic cross-sectional view of the display device according to the third embodiment. FIG. 16 is a schematic plan view of the display device according to the third embodiment. FIGS. 15 and 16 illustrate a case in which the design layer 120 has a marble pattern.

In a display device 1 according to the third embodiment, in transmissive display, light emitted from the viewing side of a display panel 100 passes through the front plate 110 and the design layer 120, and is emitted to a viewing side. The display device 1 according to the third embodiment, in addition to the transmissive display, can allow a viewer to see a color and a pattern of the design layer 120 by reflecting light (external light) incident on the display device from the viewing side.

Since the front plate 110 includes the design layer 120, the display device 1 looks just like a marble-patterned decorative plate when the display device 1 is off, and it does not look like there is the display panel 100 on a back side of the front plate 110. On the other hand, when the display device 1 is on, as illustrated in FIG. 16, an image (a string of letters ABCDE in FIG. 16) appears to emerge from the decorative plate, which provides very high design quality. By partially reducing luminance of the display device 1 to such an extent that the pattern or the like of the design layer can be seen by the viewer due to reflected light, images and the like on the display panel appears to overlap on the color of the front plate 110 and the color and pattern of the design layer 120. Note that when no design layer is provided as in the first embodiment and the like, the viewer can see the color of the front plate 110 by, for example, coloring the front plate 110.

The design layer 120 is a layer expressing a specific pattern or the like, and the pattern or the like is made visible to the viewer due to reflection of external light. The specific pattern is not particularly limited, and examples thereof include stylish geometric tones, carbon tones, marble tones, wood grain patterns, marble patterns, specific character strings, and company logos.

From the viewpoint of making a boundary between a display region 1AA and a frame region 1NA less visible, the design layer 120 is preferably placed so as to overlap the display region 1AA and the frame region 1NA of the display panel 100 in a plan view. In a plan view, the design layer 120 may be placed over an entire surface of the front plate 110, or may be placed over only part of the surface of the front plate 110. The design layer 120 is, for example, a semi-transparent picture or pattern. The specific pattern is placed in the front plate 110 as the design layer 120 by semi-transparent printing or the like. For reference, when the pattern is a wood grain pattern, a transmittance of the design layer 120 is about 60 to 80%.

The design layer 120 may have a configuration described in, for example, JP 4184711 B. The design layer 120 may be formed, for example, by printing with ink containing a glittering pigment.

The design layer 120 may be printed on a surface of a transparent base material 111 by a printing method such as gravure printing, screen printing, or ink-jet printing. Although FIG. 15 illustrates an example in which the design layer 120 is placed on the front side of the transparent base material 111, the design layer 120 may be placed on the back side of the transparent base material 111.

Typical display devices according to first to fourth comparative embodiments will be described below with reference to the drawings. In the first to fourth comparative embodiments, the adhesive member 400 illustrated in the above embodiments is not used. Note that a display panel 100R, a front plate 110R, a backlight 200R, and a bezel 310R of the first to fourth comparative embodiments can be similar to the display panel 100, the front plate 110, the backlight 200, and the bezel 310 described in the first embodiment, and thus duplicated descriptions thereof will be omitted.

### First Comparative Embodiment

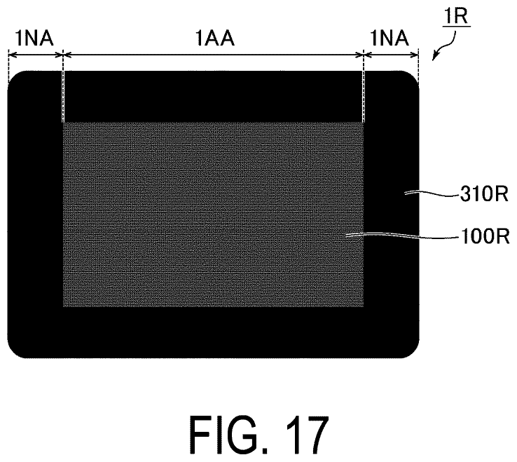

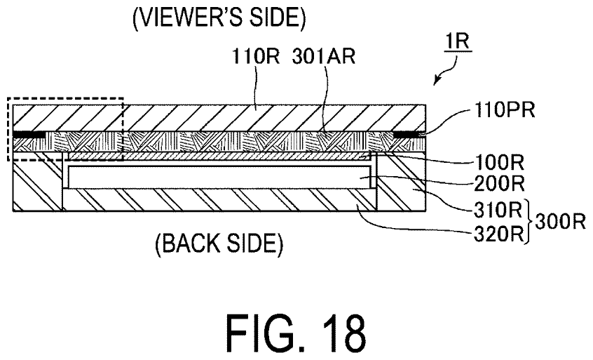

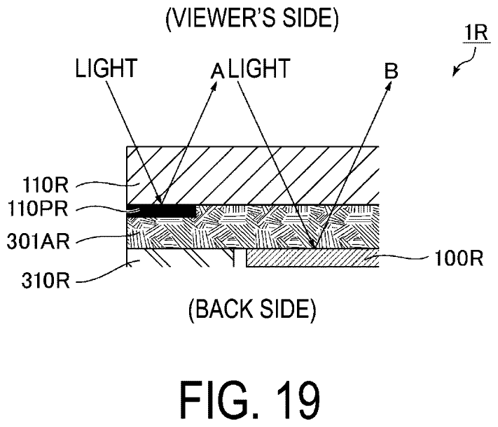

A display device 1R according to the first comparative embodiment is an example of a typical display device, and is a display device in which the display panel 100R and the front plate 110R are entirely bonded together with an optical clear adhesive sheet 301AR. FIG. 17 is a schematic plan view of a typical display device according to the first comparative embodiment. FIG. 18 is a schematic cross-sectional view of the typical display device according to the first comparative embodiment. FIG. 19 is an enlarged schematic cross-sectional view for describing reflection of external light in a region surrounded by a dotted line in FIG. 18.

In the display device 1R according to the first comparative embodiment, the display panel 100R with the backlight 200R placed on a back side thereof is stored in a housing 300R including a bezel 310R and a bottom 320R. A frame print portion 110PR is provided in a frame region 1NA of the front plate 110R using black ink or the like. The display panel 100R and the front plate 110R are bonded together with the optical clear adhesive sheet (hereinafter, also referred to as an OCA sheet) 301AR. Therefore, no air layer exists between the display panel 100R and the front plate 110R, and no interface reflection occurs between the front plate 110R and the air layer. An example of the OCA sheet 301AR is LUCIACS (registered trademark) CS986 manufactured by Nitto Denko Corporation.

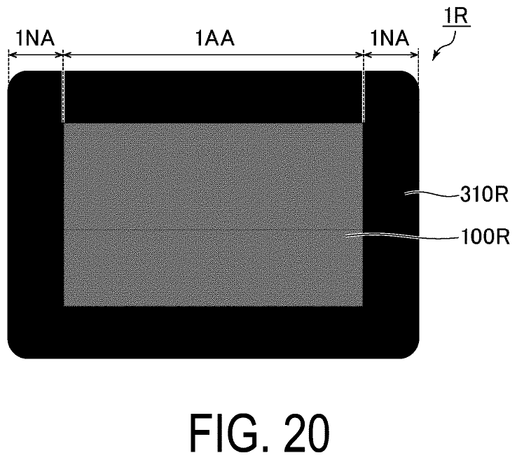

In the display device 1R of the first comparative embodiment, by making reflection characteristics of the frame print portion 110PR closer to reflection characteristics of a surface of a display region 1AA when the display device 1R is off, the frame region 1NA can be made less noticeable. In FIG. 19, A denotes a surface reflectance of the frame print portion 110PR, and B denotes a surface reflectance of the display panel 100R. By adjusting the reflectance of the frame print portion 110PR such that the surface reflectance A of the frame print portion 110PR is equal to the surface reflectance B of the display panel 100R, appearance can be improved. The display device 1R of the first comparative embodiment can have a lower reflectance of the display region 1AA than a display device according to a second comparative embodiment described below (see FIG. 20), and thus can make the display region 1AA darker as illustrated in FIG. 17, thereby making a boundary between the frame print portion 110PR and the display panel 100 less visible.

On the other hand, in addition to high costs of the OCA sheet 301AR itself, a process of bonding the front plate 110R and the display panel 100R with the OCA sheet 301AR is usually performed under vacuum, which requires expensive vacuum bonding equipment and a large amount of work time, resulting in high manufacturing costs for the display device. In addition, when bonding with the OCA sheet 301AR, air bubbles or dust may enter. Further, the display panel 100R to which the front plate 110R is bonded may warp due to temperature changes. These concerns are particularly likely to occur in large (e.g., 32 inches or larger) display devices.

The display devices of the present embodiments have a configuration in which the front plate 110 and the display panel 100R are not entirely bonded together with the OCA sheet 301AR, so that there is no risk of air bubbles or the like entering or warping of the display panel due to temperature changes, and manufacturing costs can be reduced.

### Second Comparative Embodiment

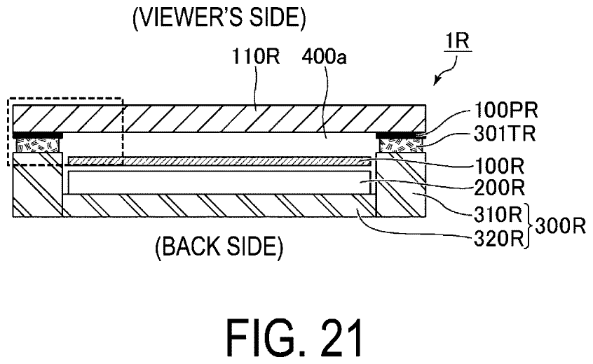

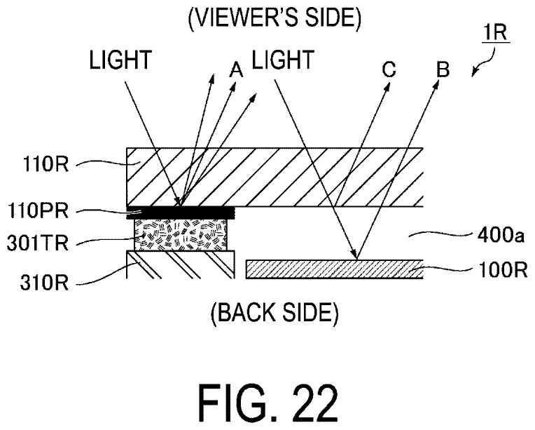

FIG. 20 is a schematic plan view of a typical display device according to the second comparative embodiment. FIG. 21 is a schematic cross-sectional view of the typical display device according to the second comparative embodiment. FIG. 22 is an enlarged schematic cross-sectional view for describing reflection of external light in a region surrounded by a dotted line in FIG. 21.

As illustrated in FIGS. 21 and 22, a display device 1R according to the second comparative embodiment includes a frame print portion 110PR on a front plate 110R, and the front plate 110R and a display panel 100R are bonded together with a double-sided tape 301TR provided in a frame region 1NA. The double-sided tape 301TR is a typical double-sided tape, and unlike the adhesive member 400 of the first embodiment, the double-sided tape 301TR is an adhesive member that does not include the light absorption layer 402, the reflective metal layer 403, or the like. Note that in the display device 1R of the second comparative embodiment, the double-sided tape 301TR is located on a back side of the frame print portion 110PR, so that a bonded portion where the double-sided tape 301TR is placed is not visible from the viewing side. An example of the double-sided tape is Double-faced Adhesive Tape for Fixing of LCD Components 3800 Series, manufactured by SEKISUI CHEMICAL CO., LTD.

The display device 1R of the second comparative embodiment includes an air layer 400a between the front plate 110R and the display panel 100R, so that interface reflection occurs between the front plate 110R and the air layer 400a. In the second comparative embodiment, even when reflection characteristics of the frame print portion 110PR are made closer to reflection characteristics of a surface of a display region 1AA when not displayed, the frame print portion 110PR is more noticeable than in the first comparative embodiment because the air layer 400a exists at a position overlapping the display region 1AA.

In FIG. 22, A denotes a surface reflectance of the frame print portion 110PR, B denotes a surface reflectance of the display panel 100R, and C denotes an interface reflectance between the front plate 110R and the air layer 400a. In principle, when the surface reflectance of the frame print portion 110PR can be adjusted such that the surface reflectance A of the frame print portion 110PR is the sum of the surface reflectance B of the display panel 100R and the interface reflectance C between the front plate 110R and the air layer 400a, a boundary between the frame print portion 110PR and the display region 1AA can be less visible. However, while the surface reflection of the frame print portion 110PR is, for example, a light scattering reflection due to ink printed on the surface of the frame print portion 110PR, the interface reflection between the front plate 110R and the air layer 400a is a specular reflection, so that it is extremely difficult to bring the surface reflectance A close to the sum of the surface reflectance B and the interface reflectance C, including angular characteristics, and thus the frame region 1NA in which the frame print portion 110PR is placed is noticeable.

### Third Comparative Embodiment

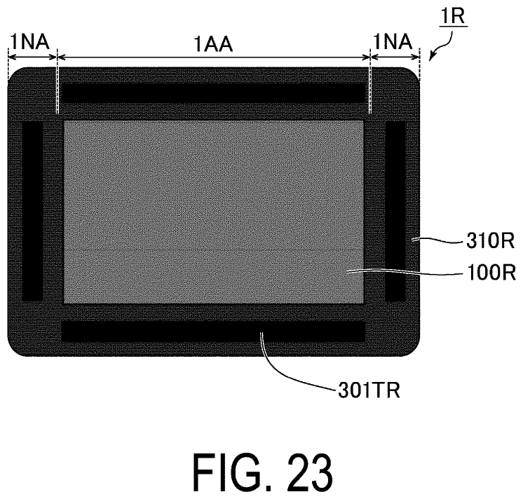

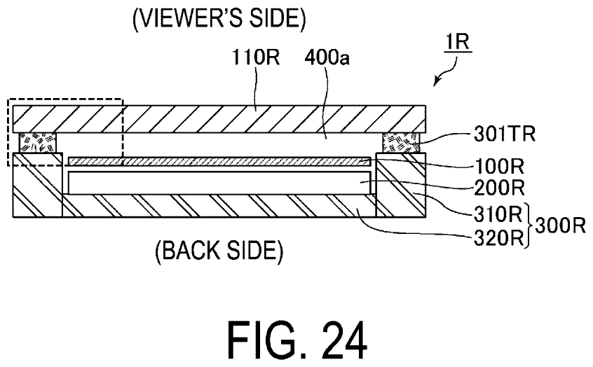

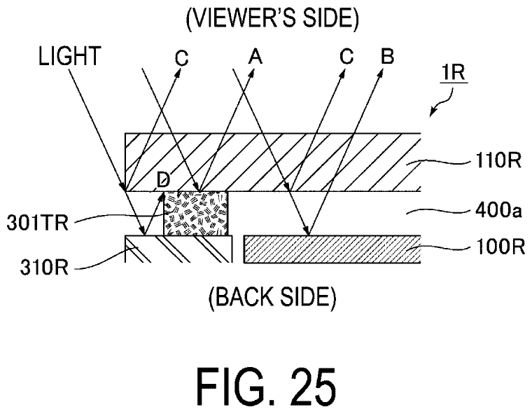

FIG. 23 is a schematic plan view of a typical display device according to the third comparative embodiment. FIG. 24 is a schematic cross-sectional view of the typical display device according to the third comparative embodiment. FIG. 25 is an enlarged schematic cross-sectional view for describing reflection of external light in a region surrounded by a dotted line in FIG. 24.

As illustrated in FIGS. 24 and 25, in a display device 1R according to the third comparative embodiment, a frame print portion 110PR is not provided on a front plate 110R, and the front plate 110R and a bezel 310R are bonded together with an adhesive member 301TR. As the adhesive member 301TR, for example, the OCA sheet 301AR illustrated in the first comparative embodiment, or the double-sided tape 301TR illustrated in the second comparative embodiment can be used. The display device 1R of the third comparative embodiment includes an air layer 400a between the front plate 110R and the display panel 100R, so that interface reflection occurs between the front plate 110R and the air layer 400a.

In the display device 1R of the third comparative embodiment, in a non-bonded portion where the double-sided tape 301TR or the like is not placed, when a tone of the bezel 310R is made similar to a tone of a display region 1AA when the display device is off, a difference in appearance between the display region 1AA and the bezel 310R is less noticeable than that illustrated in the first comparative embodiment. As the display region 1AA and the non-bonded portion of a frame region 1NA have an air layer on a back side of the front plate 110R, interface reflection between the front plate 110R and the air layer will occur. Note that in the display device 1R of the third comparative embodiment, a surface of the display panel 100R and a surface of the bezel 310R are also visible to the viewer, so that it is difficult to make the display region 1AA and the frame region 1NA look the same.

When an opaque component is used as the adhesive member 301TR, reflection occurs on a surface of the opaque component at the bonded portion. On the other hand, when a transparent component is used as the adhesive member 301TR, reflection occurs on the surface of the frame portion (bezel 310R) at the bonded portion. However, in either case, no interface reflection with the air layer occurs. Thus, reflections with different characteristics occur in the bonded portion and the non-bonded portion, resulting in a difference in appearance.

In FIG. 25, A denotes a surface reflectance of the double-sided tape 301TR, B denotes a surface reflectance of the display panel 100R, and C denotes an interface reflectance between the front plate 110R and the air layer 400a. In principle, by adjusting the reflectance of the double-sided tape 301TR (base material and adhesive layer) such that the surface reflectance A of the double-sided tape 301TR is the sum of the surface reflectance B of the display panel 100R and the interface reflectance C between the front plate 110R and the air layer 400a, a boundary between the display region 1AA and the bonded portion where the double-sided tape 301TR is placed can be less visible. However, since the surface reflection of the double-sided tape 301TR is usually a light scattering reflection, and the interface reflection between the front plate 110R and the air layer 400a is a specular reflection, it is extremely difficult to bring the surface reflectance A close to the sum of the surface reflectance B and the interface reflectance C, including angular characteristics, and the bonded portion is noticeable.

Note that when the double-sided tape 301TR is transparent, light is not reflected on the surface of the double-sided tape 301TR, but is reflected on the surface of the bezel 310R. Therefore, the surface reflectance A is replaced with the surface reflectance of the bezel 310R, and the reflectance of the surface of the bezel 310R is adjusted so that the surface reflectance A=the surface reflectance B+ the interface reflectance C. When the double-sided tape 301TR is opaque (e.g., when a black base material is used as the double-sided tape 301TR), a tone of the double-sided tape 301TR is close to a tone of the surroundings thereof, thereby making the double-sided tape 301TR less noticeable to a certain extent.

### Fourth Comparative Embodiment

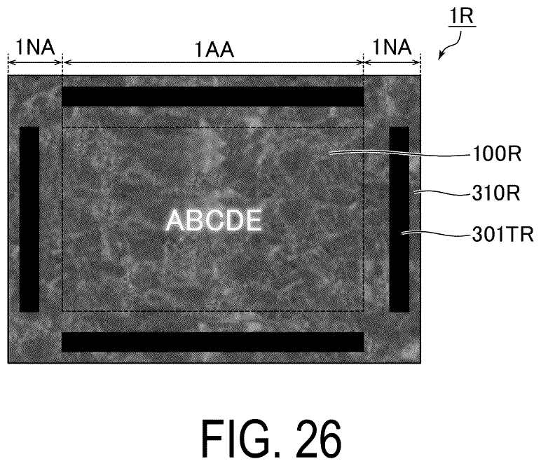

FIG. 26 is a schematic plan view of a typical display device, describing an aspect in which a front plate includes a design layer. When a front plate 110R included in a typical display device 1R includes a design layer, an appearance of a pattern when the display device 1R is off differs depending on a position of the display device 1R, resulting in poor design. To be specific, as illustrated in FIG. 26, an appearance of a bonded portion where a double-sided tape 301TR is placed on a bezel differs from an appearance of a non-bonded portion where the double-sided tape 301TR is not placed and an appearance of a display region.

In contrast to the second to fourth comparative embodiments, the display devices according to the embodiments can make the appearance of the bonded portion closer to the appearance of the display region 1AA by setting both |α1−β1| and |α2−β21 to 3.0% or less.

Although the embodiments of the disclosure have been described above, the disclosure is not limited to the embodiments described above, and can be embodied in various aspects without departing from the gist thereof. The multiple constituent elements disclosed in the above embodiments can be modified as appropriate. For example, some of all the constituent elements illustrated in one embodiment may be added to the constituent elements of another embodiment, or some of all the constituent elements illustrated in one embodiment may be deleted from that embodiment. Each of the embodiments can also be combined.

The drawings mainly illustrate the corresponding constituent elements schematically in order to facilitate understanding of the disclosure, and the thickness, length, number, spacing, and the like of each of the constituent elements illustrated in the drawings may be different from the actual ones for convenience of drawing preparation. The configurations of the constituent elements illustrated in the above-described embodiments are merely examples and are not particularly limited, and it is needless to say that various modifications can be made without substantially departing from the effects of the disclosure.

### EXAMPLES

The disclosure will be described in more detail below with reference to experimental examples, but the disclosure is not limited to these experimental examples.

### First Experimental Example

In a first experimental example, as illustrated in FIG. 4, adhesive members 400 were prepared in each of which a first adhesive layer 401a, a light absorption layer 402, a reflective metal layer 403, a base material 404, and a second adhesive layer 401b were placed in this order from the viewing side.

As the base material 404, a transparent PET film having a thickness of 50 μm (Lumirror manufactured by Toray Industries, Inc., total light transmittance: 92%, haze: 0.91%) was used. An aluminum thin film having a thickness of 150 nm was formed by sputtering on one surface of the base material 404 as the reflective metal layer 403. An SCI and an SCE of the reflective metal layer 403 were 85.1% and 2.3%, respectively.

An amount of a black pigment (carbon black) added to resin (Hydric manufactured by Dainichiseika Color & Chemicals Mfg. Co., Ltd.) was changed so as to obtain total light transmittances of conditions 1 to 6 shown in Table 2 below, and light absorption layers 402 each having a thickness of 5 μm were prepared and layered on the reflective metal layers 403, respectively. Thereafter, the first adhesive layer 401a having a thickness of 50 μm was layered on the light absorption layer 402 side, and the second adhesive layer 401b having a thickness of 50 μm was layered on a surface of the base material 404 opposite to the surface on which the reflective metal layer 403 was formed, thereby preparing the adhesive members for the first experimental example. As the first adhesive layer 401a and the second adhesive layer 401b, LUCIACS CS986 manufactured by Nitto Denko Corporation was used.

### Second Experimental Example

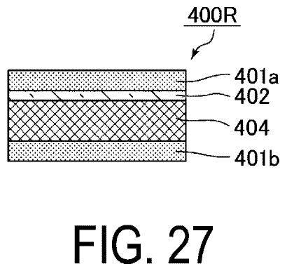

FIG. 27 is a schematic cross-sectional view of an adhesive member 400R prepared for a second experimental example. In the second experimental example, as illustrated in FIG. 27, adhesive members 400R were prepared in each of which a first adhesive layer 401a, a light absorption layer 402, a base material 404, and a second adhesive layer 401b were placed in this order from the viewing side. In the second experimental example, the reflective metal layer 403 was not placed, and a white PET film having a thickness of 20 μm (Lumirror manufactured by Toray Industries, Inc., total light transmittance: 20%, haze: 70%) was used as the base material 404. An SCI and an SCE of the white PET film were 73.4% and 68.9%, respectively.

Light absorption layers 402 of conditions 1 to 6 were each layered on one surface of the white PET film and then the first adhesive layer 401a and the second adhesive layer 401b were layered in a manner similar to the first experimental example to prepare the adhesive members for the second experimental example.

### Preparation of Display Device

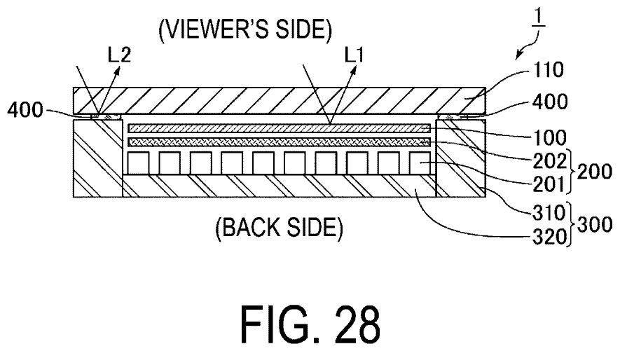

FIG. 28 is a schematic cross-sectional view of a display device using the adhesive member for the first experimental example. The same applies to a display device using the adhesive member for the second experimental example. In the first experimental example, a liquid crystal panel was used as a display panel 100, and a direct backlight 200 including a diffuser plate 202 and LEDs 201 as light sources was used (see FIG. 28). The adhesive members for the first and second experimental examples having the light absorption layers of conditions 1 to 6 were each placed on a bezel so as to surround the display panel 100, and the bezel and a front plate (a glass plate having a thickness of 1.5 mm) were bonded together using each adhesive member to prepare the display devices (see FIG. 1).

An SCI and an SCE of light L1 reflected in a display region of the display device were measured, and results are shown in Table 1. The SCI and the SCE were measured using a CM-700d spectrophotometer manufactured by KONICA MINOLTA INC., in accordance with JIS Z 8722:2009. As shown in Table 1, the SCE of the display region is substantially zero, which means that the reflection is substantially a specular reflection.

TABLE 1
Display region

| SCI (α1) | SCE (α2) |
|---|---|
| 13.10% | 0.10% |

An SCI and an SCE of light L2 reflected at a bonded portion where each adhesive member is placed on the bezel were measured. Results are shown in Table 2 below for the first experimental example and in Table 3 below for the second experimental example. An absolute value of a difference between α1 and β1 (|α1−β1|). an absolute value of a difference between α2 and β2 (|α2−β21), and a reflectance of 2 relative to β1 (β2/1)×100 [%] are shown in Tables 2 and 3 below.

In the tables below, α1 denotes a reflectance of a region overlapping the display panel in a plan view (display region) measured from a front plate side by an SCI method. β1 denotes a reflectance of a region overlapping the bezel in a plan view (bonded portion) measured from the front plate side by the SCI method. α2 denotes a reflectance of the region overlapping the display panel in a plan view (display region) measured from the front plate side by an SCE method. β2 denotes a reflectance of the region overlapping the bezel in a plan view (bonded portion) measured from the front plate side by the SCE method.

TABLE 2
First experimental example

| | Metal | Light | Bonded portion | | | | |
|---|---|---|---|---|---|---|---|
| Base | reflective | absorption | SCI | SCE | \|α1 − | \|α2 − | (β2/β1) × |
| material | layer | layer | (β1) | (β2) | β1\| | β2\| | 100 |
| Transparent | Aluminum | Condition 1: | 6.60% | 0.20% | 6.50% | 0.10% | 3.0% |
| PET film | thin film | transmittance of 2.4% | | | | | |
| | | Condition 2: | 7.70% | 0.20% | 5.40% | 0.10% | 2.6% |
| | | transmittance of 6.4% | | | | | |
| | | Condition 3: | 8.90% | 0.40% | 4.20% | 0.30% | 4.5% |
| | | transmittance of 15.4% | | | | | |
| | | Condition 4: | 13.70% | 0.40% | 0.60% | 0.30% | 2.9% |
| | | transmittance of 25.5% | | | | | |
| | | Condition 5: | 18.40% | 0.80% | 5.30% | 0.70% | 4.3% |
| | | transmittance of 34.4% | | | | | |
| | | Condition 6: | 29.50% | 1.50% | 16.40% | 1.40% | 5.1% |
| | | transmittance of 48.2% | | | | | |

The larger the value of |α1−β1| and/or |α2−β2| was, the more noticeable the boundary between the display region and the bonded portion tended to be. In condition 4 of the first experimental example, the SCI and the SCE of the bonded portion were close to the SCI and the SCE of the display region shown in Table 1, and the boundary between the display region and the bonded portion was hardly visible with the naked eye, resulting in the best appearance. From these results, it is considered that |α1−β1| and |α2−β2| are preferably 3.0% or less, and more preferably 1.5% or less. To be specific, when the reflectances SCI and SCE of the display region are the values shown in Table 1, the SCI of the bonded portion is preferably from 10.1% to 16.1%, and the SCE of the bonded portion is preferably from 0% to 3.1%. In this case, the SCI of the bonded portion is more preferably from 11.6% to 14.6%, and the SCE of the bonded portion is more preferably from 0% to 1.6%.

TABLE 3
Second experimental example

| | Metal | Light | Bonded portion | | | | |
|---|---|---|---|---|---|---|---|
| Base | reflective | absorption | SCI | SCE | \|α1 − | \|α2 − | (β2/β1) × |
| material | layer | layer | (β1) | (β2) | β2\| | β2\| | 100 |
| White | None | Condition 1: | 6.50% | 0.20% | 6.60% | 0.10% | 3.1% |
| PET film | | transmittance of 2.4% | | | | | |
| | | Condition 2: | 7.40% | 0.30% | 5.70% | 0.20% | 4.1% |
| | | transmittance of 6.4% | | | | | |
| | | Condition 3: | 7.40% | 1.10% | 5.70% | 1.00% | 14.9% |
| | | transmittance of 15.4% | | | | | |
| | | Condition 4: | 9.70% | 2.80% | 3.40% | 2.70% | 28.9% |
| | | transmittance of 25.5% | | | | | |
| | | Condition 5: | 11.50% | 5.00% | 1.60% | 4.90% | 43.5% |
| | | transmittance of 34.4% | | | | | |
| | | Condition 6: | 17.00% | 10.20% | 3.90% | 10.10% | 60.0% |
| | | transmittance of 48.2% | | | | | |

In the second experimental example, the boundary between the display region and the bonded portion was noticeable in all conditions 1 to 6. The white PET sheet used as the base material in the second experimental example caused diffuse reflection and had a large SCE, thus in condition 5, although the SCI of the bonded portion was close to the SCI of the display region, the SCE of the bonded portion was significantly different from the SCE of the display region and it is thought that there were no conditions under which both reflection characteristics were similar. In this case, when observed from a specular reflection direction (normal direction), the boundary was hardly visible, but when observed from an oblique direction, the boundary was noticeable.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display device comprising:
a display panel;
a housing configured to store the display panel and including a bezel placed around the display panel in a plan view;
a front plate placed on a viewing side of the display panel, and overlapping the display panel and at least part of the bezel in a plan view; and
an adhesive member placed between the bezel and the front plate,
wherein an air layer is provided between the display panel and the front plate, and
in a case in which α1 denotes a reflectance of a region overlapping the display panel in a plan view measured by an SCI method from a front plate side, 31 denotes a reflectance of a region overlapping the bezel in a plan view measured by the SCI method from the front plate side, α2 denotes a reflectance of the region overlapping the display panel in a plan view measured by an SCE method from the front plate side, and β2 denotes a reflectance of the region overlapping the bezel in a plan view measured by the SCE method from the front plate side,
an absolute value of a difference between α1 and β1 is 3.0% or less, and
an absolute value of a difference between α2 and β2 is 3.0% or less.

2. The display device according to claim 1,
wherein the absolute value of the difference between α1 and β1 is 1.5% or less, and
the absolute value of the difference between α2 and β2 is 1.5% or less.

3. The display device according to claim 1,
wherein the adhesive member includes a light absorption layer and a reflective metal layer.

4. The display device according to claim 3,
wherein the adhesive member includes, from the viewing side, the light absorption layer and the reflective metal layer in this order.

5. The display device according to claim 3,
wherein a surface of the adhesive member on the viewing side is formed of a first adhesive layer.

6. The display device according to claim 5,
wherein a surface of the adhesive member on a back side is formed of a second adhesive layer.

7. The display device according to claim 1,
wherein a reflectance of β2 relative to β1 is less than 5%.

8. The display device according to claim 1,
wherein the adhesive member overlaps part of the bezel in a plan view.

9. The display device according to claim 1,
wherein the adhesive member overlaps an entire surface of the bezel in a plan view.

10. The display device according to claim 1,
wherein part of the adhesive member overlaps part of the display panel in a plan view.

11. The display device according to claim 10,
wherein the adhesive member includes a light blocking layer.

12. The display device according to claim 1,
wherein the front plate includes a design layer.

13. The display device according to claim 1,
wherein the front plate has a total light transmittance of 5% or more.

14. The display device according to claim 1,
wherein local dimming is possible.
